(19) United States
(12) Patent Application Publication
(10) Pub. No.: US 2025/0160057 A1
(43) Pub. Date: May 15, 2025

(54) MICRO LED AND MICRO LED DISPLAY PANEL

(71) Applicant: JADE BIRD DISPLAY (SHANGHAI) LIMITED, SHANGHAI (CN)

(72) Inventors: Qunchao XU, Shanghai (CN); Weisin TAN, Shanghai (CN)

(21) Appl. No.: 18/940,885

(22) Filed: Nov. 8, 2024

(30) Foreign Application Priority Data
Nov. 9, 2023 (WO) PCT/CN2023/130739

(51) Int. Cl. H01L 33/08; H01L 25/075; H01L 25/16; H01L 33/60; H01L 33/62

(52) U.S. Cl. CPC H10H 20/813; H01L 25/0753; H01L 25/167; H10H 20/856; H10H 20/857

(57) ABSTRACT

A micro LED includes a bonding layer provided at a bottom of the micro LED and two or more light emitting mesas provided on the bonding layer and disposed in a vertical direction from top to bottom, wherein the two or more light emitting mesas are electrically connected in series.

### CROSS-REFERENCE TO RELATED APPLICATIONS

The present disclosure claims the benefits of priority to PCT Application No. PCT/CN2023/130739, filed on Nov. 9, 2023, which is incorporated herein by reference in its entirety.

### TECHNICAL FIELD

The present disclosure generally relates to micro LED manufacturing technology, and more particularly, to a micro LED and a micro LED display panel.

### BACKGROUND

Inorganic micro pixel light emitting diodes, also referred to as micro light emitting diodes, micro LEDs, or μ-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

A micro LED can include a light emitting mesa and electrical connection to electrodes, so that the micro LED can be controlled. Since a pitch and a dimension of the micro LED become smaller and smaller, light emission efficiency may seriously degrade.

### SUMMARY OF THE DISCLOSURE

Embodiments of the present disclosure provide a micro LED. The micro LED includes a bonding layer provided at a bottom of the micro LED; and two or more light emitting mesas provided on the bonding layer and disposed in a vertical direction from top to bottom, wherein the two or more light emitting mesas are electrically connected in series.

Embodiments of the present disclosure also provide a micro LED display panel. The micro LED display panel includes an integrated circuit (IC) backplane including a bottom pad array, the bottom pad array comprising a plurality of bottom pads; and a micro LED array formed on the IC backplane, the micro LED array comprising a plurality of micro LEDs. One micro LED of the plurality of micro LEDs is electrically connected to one bottom pad of the plurality of bottom pads, and each of the plurality of micro LEDs includes a bonding layer bonded with the IC backplane, and two or more light emitting mesas formed on the bonding layer; wherein the two or more light emitting mesas are disposed in a vertical direction from top to bottom and electrically connected in series.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a structural diagram showing a sectional view of an exemplary micro LED display panel, according to some embodiments of the present disclosure.

FIG. 2 is a circuit diagram schematically illustrating two light emitting mesas electrically connected in series, according to some embodiments of the present disclosure.

FIG. 3 illustrates a structural diagram showing a sectional view of another exemplary micro LED display panel, according to some embodiments of the present disclosure.

FIG. 4A illustrates a structural diagram showing a top view of micro LED display panel shown in FIG. 3, according to some embodiments of the present disclosure.

FIG. 4B illustrates a structural diagram showing another top view of micro LED display panel shown in FIG. 3, according to some embodiments of the present disclosure.

FIG. 5 illustrates a structural diagram showing a sectional view of another exemplary micro LED display panel, according to some embodiments of the present disclosure.

FIG. 6A illustrates a structural diagram showing a top view of micro LED display panel shown in FIG. 5 with top conductive layer and enhance pad removed, according to some embodiments of the present disclosure.

FIG. 6B illustrates a structural diagram showing another top view of micro LED display panel shown in FIG. 5 with top conductive layer and enhance pad removed, according to some embodiments of the present disclosure.

FIG. 7 illustrates a structural diagram showing a top view of a micro LED display panel, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

Embodiments of the present disclosure provide a micro LED having improved light emission efficiency. The micro LED includes multiple light emitting mesas in series.

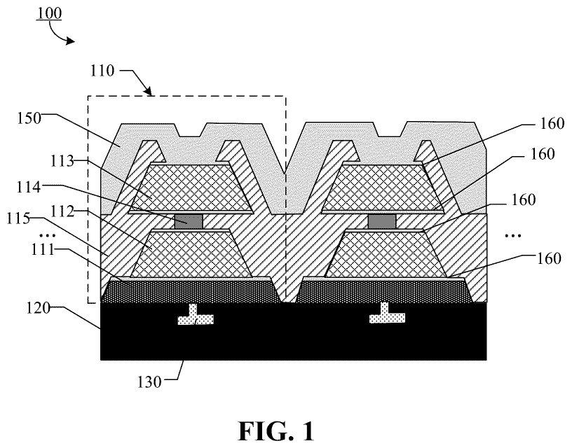

FIG. 1 illustrates a structural diagram showing a sectional view of an exemplary micro LED display panel 100, according to some embodiments of the present disclosure. A micro LED consistent with the present disclosure includes two or more light emitting mesas electrically connected in series. In FIG. 1, two adjacent micro LEDs are illustrated. Micro LED display panel 100 includes a micro LED array including a plurality of micro LEDs 110 and an IC (integrated Circuit) backplane 120. The plurality of micro LEDs 110 are provided on IC backplane 120.

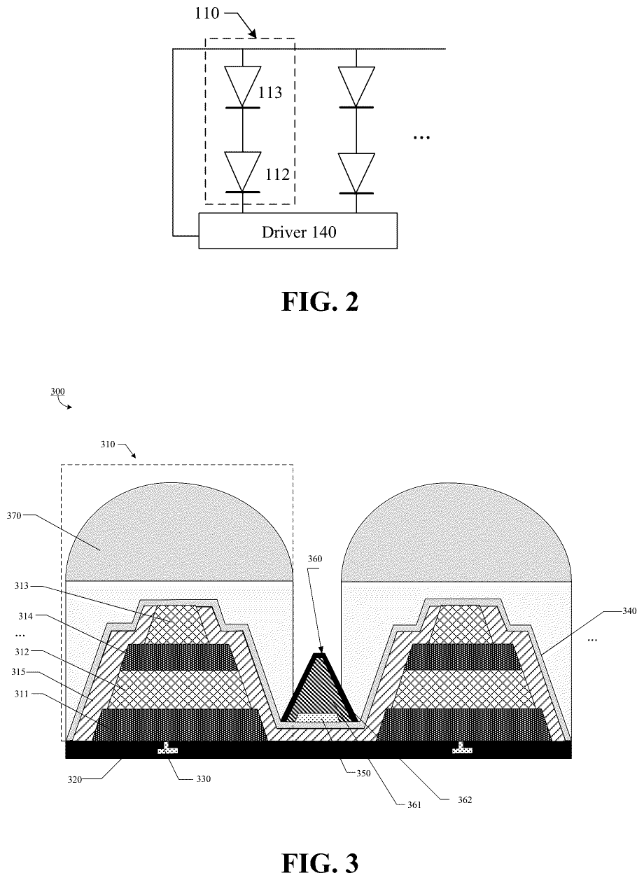

As shown in FIG. 1, micro LED 110 includes a bonding layer 111. Bonding layer 111 is bonded with IC backplane 120. In some embodiments, bonding layer 111 is bonded with IC backplane 120 by a bottom pad 130. In some embodiments, a material of bonding layer 111 is metal. For example, the material may include: Al, Au, Rh, Ag, Cr, Ti, Pt, Sn, Cu, etc. The material may also include one or more metal alloys, for example, AuSn, TiW, and the like. A first light emitting mesa 112 and a second light emitting mesa 113 are provided on bonding layer 111 and disposed in a vertical direction from bottom to top. First light emitting mesa 112 is formed on bonding layer 111 and electrically connected to bonding layer 111. Second light emitting mesa 113 is provided above first light emitting mesa 112. First light emitting mesa 112 and a second light emitting mesa 113 are electrically connected in series. For example, a bottom of first light emitting mesa 112 is connected to a first electrode (e.g., P-pad, not shown), and a top of second light emitting mesa 113 is connected to a second electrode (e.g., N-pad, not shown). A top of first light emitting mesa 112 is connected to a bottom of second light emitting mesa 113. FIG. 2 is a circuit diagram schematically illustrating the two light emitting mesas electrically connected in series, according to some embodiments of the present disclosure. As shown in FIG. 2, a light emitting mesa (e.g., light emitting mesa 112 or 113) can be considered as a diode, and first light emitting mesa 112 and second light emitting mesa 113 are electrically connected in series. Referring to FIG. 1 and FIG. 2, a driver 140 can be connected to micro LED 110 and configured to control each micro LED 110. In some embodiments, driver 140 can be integrated into IC backplane 120.

Referring to FIG. 1, a connection structure is provided between first light emitting mesa 112 and second light emitting mesa 113 to connect first light emitting mesa 112 and second light emitting mesa 113 in series. In this example, the connection structure is a metal via 114. Since metal via 114 only covers a small portion of the surface of first light emitting mesa 112, a light emitting area of first light emitting mesa 112 and a light emitting area of second light emitting mesa 113 can be the same. First light emitting mesa 112 and second light emitting mesa 113 have the same size.

In some embodiments, an area of a top surface of bonding layer 111 is greater than an area of a bottom surface of first light emitting mesa 112.

In some embodiments, micro LED 110 further includes dielectric material 115 filled between and around first light emitting mesa 112 and second light emitting mesa 113. Dielectric material 115 is transparent. A material of dielectric material 115 can be selected from one or more of SiO₂, SiON, Al₂O₃, or SiN, etc.

In some embodiment, micro LED display panel 100 further includes a top conductive layer 150 continuously formed on top surfaces of the plurality of micro LEDs 110. Top conductive layer 150 electrically connects to the top surface of second light emitting mesa 113 and connects to the second electrode (e.g., N-pad). Since bonding layer 111 of micro LED 110 is connected to IC backplane panel 120 with respective bottom pad 130, each micro LED 110 of the plurality of micro LEDs can be controlled independently, for example, by driver 140 (as shown in FIG. 2).

In some embodiments, micro LED display panel 100 further includes conductive layers 160 provided at both top and bottom of each light emitting mesa 112, 113 to improve electrical connection performance.

FIG. 3 illustrates a structural diagram showing a sectional view of another exemplary micro LED display panel 300, according to some embodiments of the present disclosure. Micro LED display panel 300 includes a micro LED array including a plurality of micro LEDs 310 provided on an IC backplane 320. As shown in FIG. 3, micro LED 310 includes a first bonding layer 311, a first light emitting mesa 312, and a second light emitting mesa 313. In this example, a connection structure provided between first light emitting mesa 312 and second light emitting mesa 313 to connect first light emitting mesa 312 and second light emitting mesa 313 in series is a second bonding layer 314. In some embodiments, a material of second bonding layer 314 is metal. For example, the material may include: Al, Au, Rh, Ag, Cr, Ti, Pt, Sn, Cu, etc. The material may also include one or more metal alloys, for example, AuSn, TiW, and the like. A light emitting area of first light emitting mesa 312 is greater than a light emitting area of second light emitting mesa 313. In some embodiments, an area of a bottom surface of second bonding layer 314 is the same as an area of a top surface of first light emitting mesa 312.

In some embodiments, micro LED panel 300 further includes dielectric material 315 filled between and around first light emitting mesa 312 and second light emitting mesa 313. Dielectric material 315 is transparent. A material of dielectric material 315 can be selected from one or more of SiO₂, SiON, Al₂O₃, or SiN, etc.

Referring to FIG. 3, micro LED display panel 300 further includes a top conductive layer 340 continuously formed on top surfaces of the plurality of micro LEDs 310. Top conductive layer 340 electrically connects to the top surface of second light emitting mesa 313 and connects to a second electrode (e.g., N-pad, not shown). Bonding layer 311 of micro LED 310 is connected to IC backplane 320 with a bottom pad 330. As a result, each micro LED 310 of the plurality of micro LEDs can be controlled independently via IC backplane 320.

In some embodiments, micro LED display panel 300 further includes an enhance pad 350 provided on top conductive layer 340 to increase the conductivity of top conductive layer 340. In some embodiments, enhance pad 350 is provided between adjacent micro LEDs. In some embodiments, enhance pad 350 has a mesh structure.

In some embodiments, micro LED display panel 300 further includes an isolation structure 360 provided between adjacent micro LEDs to reduce light interference between the adjacent micro LEDs. In some embodiments, isolation structure 360 is provided on top conductive layer 340. A bottom of isolation structure 360 is lower than or equal to a bottom of first light emitting mesa 312, and a top of isolation structure 360 is higher than or equal to a bottom of second light emitting mesa 313. Therefore, isolation structure 360 can prevent light interference between first light emitting mesa 312 of adjacent micro LEDs. In some embodiments, isolation structure 360 has a structure with a truncated cone shape. That is, an area of a bottom surface of isolation structure 360 is greater than an area of a top surface of isolation structure 360. In some embodiments, isolation structure 360 includes an isolation core 361 and a reflective layer 362 formed on a surface of isolation core 361. Isolation core 361 is provided to form an angle suitable for reflective layer 362. In some embodiments, a material of isolation core 361 is photosensitive polyimide (PSPI). A material of reflective layer 362 can be any materials with high reflectivity, such as Au, Ag, an omni-directional reflector (ODR), or a distributed Bragg reflector (DBR). Therefore, isolation structure 360 can further reflect the light emitted from micro LED 310 upwards, thereby further improving light emission efficiency. In some embodiments, enhance pad 350 is provided at a bottom of isolation structure 360.

In some embodiments, micro LED display panel 300 further includes a plurality of micro lenses 370 corresponding to the plurality of micro LED. Micro lens 370 is provided on micro LED 310 to cover a light emitting area of micro LED 310.

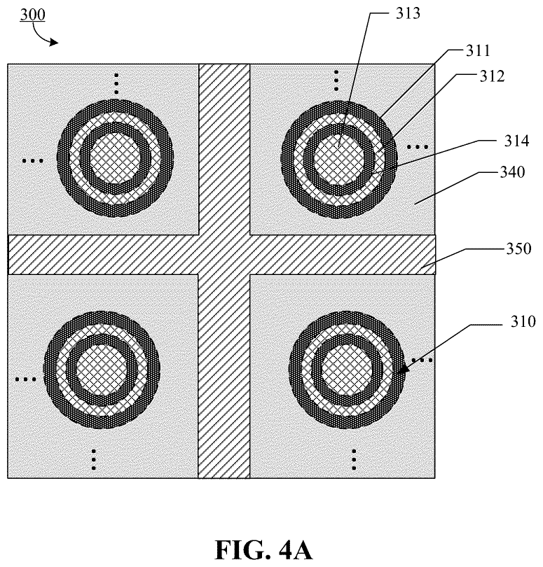

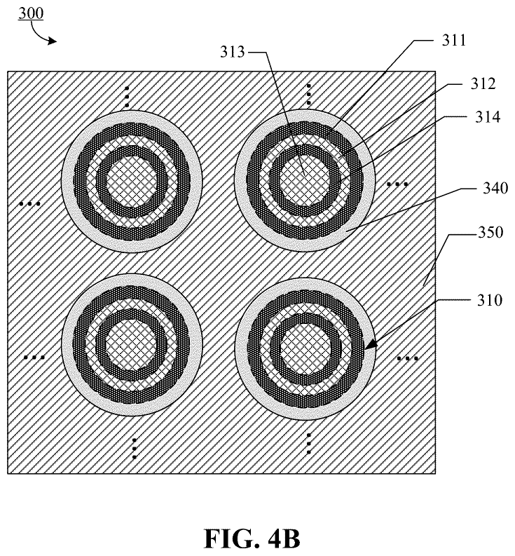

FIG. 4A illustrates a structural diagram showing a top view of micro LED 300 display panel shown in FIG. 3, according to some embodiments of the present disclosure. Consistent with FIG. 3, referring to FIG. 4A, top conductive layer 340 is continuously formed on micro LED display panel 300. In this example, enhance pad 350 is provided on top conductive layer 340 between adjacent micro LEDs 310 (including first bonding layer 311, first light emitting mesa 312, second light emitting mesa 313, and second bonding layer 314) and illustrated as a grid. A shape of exposed part of top conductive layer 340 is rectangular.

FIG. 4B illustrates a structural diagram showing another top view of micro LED display panel 300 shown in FIG. 3, according to some embodiments of the present disclosure. Consistent with FIG. 3, referring to FIG. 4B, top conductive layer 340 is continuously formed on micro LED display panel 300. In this example, enhance pad 350 is provided on top conductive layer 340 between adjacent micro LEDs 310 (including first bonding layer 311, first light emitting mesa 312, second light emitting mesa 313, and second bonding layer 314) and illustrated as a mesh. A shape of exposed part of top conductive layer 340′ is round.

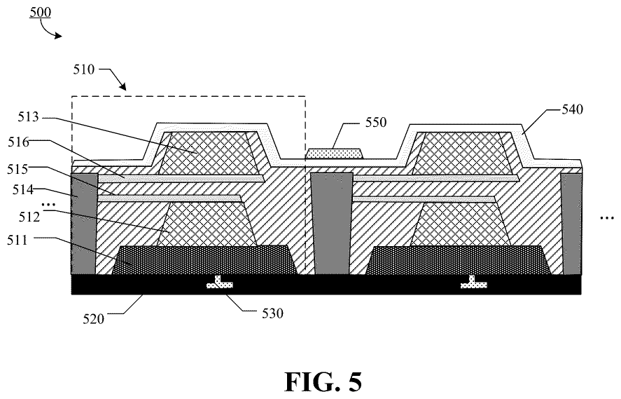

FIG. 5 illustrates a structural diagram showing a sectional view of another exemplary micro LED display panel 500, according to some embodiments of the present disclosure. Micro LED display panel 500 includes a micro LED array including a plurality of micro LED 510 provided on an IC backplane 520. As shown in FIG. 5, micro LED 510 includes a bonding layer 511, a first light emitting mesa 512, and a second light emitting mesa 513. Micro LED 510 further includes a side connection structure 514 provided at a side of micro LED 510 (e.g., including bonding layer 511, first light emitting mesa 512, and second light emitting mesa 513). Side connection structure 514 connects first light emitting mesa 512 and second light emitting mesa 513 in series. First light emitting mesa 512 further includes a top connection layer 515 formed at a top of first light emitting mesa 512 and electrically connected to side connection structure 514. Second light emitting mesa 513 includes a bottom connection layer 516 formed at a bottom of second light emitting mesa 513 and electrically connected to side connection structure 514. Therefore, first light emitting mesa 512 and second light emitting mesa 513 are electrically connected in series by top connection layer 515, side connection structure 514, and bottom connection layer 516. In some embodiments, a bottom of side connection structure 514 is aligned with a bottom of bonding layer 511, but not connected to bonding layer 511. A top of side connection structure 514 is aligned with the bottom of second light emitting mesa 513. In some embodiments, side connection structure 514 is non-transparent. A material of side connection structure 514 is metal. Therefore, side connection structure 514 can also isolate light interference from adjacent micro LEDs. In some embodiments, side connection structure 514 surrounds half of a circumference of micro LED 510 (e.g., including bonding layer 511, first light emitting mesa 512, and second light emitting mesa 513).

In some embodiments, top connection layer 515 and bottom connection layer 516 are transparent. In some embodiments, top connection layer 515 and bottom connection layer 516 are TCO (transparent conductive oxide) thin layers, for example, ITO (Indium Tin Oxide) layers, AZO (Antimony doped Zinc Oxide) layers, ATO (Antimony doped Tin Oxide) layers, FTO (Fluorine doped Tin Oxide) layers, and the like.

In some embodiments, a light emitting area of first light emitting mesa 512 and a light emitting area of second light emitting mesa 513 are the same. First light emitting mesa 512 and second light emitting mesa 513 have the same size.

In some embodiments, a top surface of bonding layer 511 is greater than a bottom surface of first light emitting mesa 512.

In some embodiments, micro LED display panel 500 further includes a top conductive layer 540 continuously formed on top surfaces of the plurality of micro LEDs. Top conductive layer 540 electrically connects to the top surface of second light emitting mesa 513 and connects to a second electrode (e.g., N-pad, not shown). Since bonding layer 511 of micro LED 510 is connected to IC backplane 520 with a bottom pad 530. As a result, each micro LED 510 of the plurality of micro LEDs can be controlled independently via IC backplane 520.

In some embodiments, micro LED display panel 500 further includes an enhance pad 550 provided on top conductive layer 540 to increase the conductivity of top conductive layer 540. In some embodiments, enhance pad 550 is provided between adjacent micro LEDs. In some embodiments, enhance pad 550 has a mesh structure.

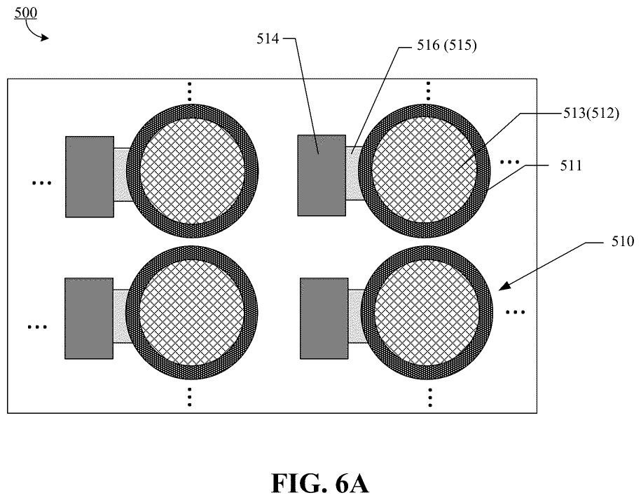

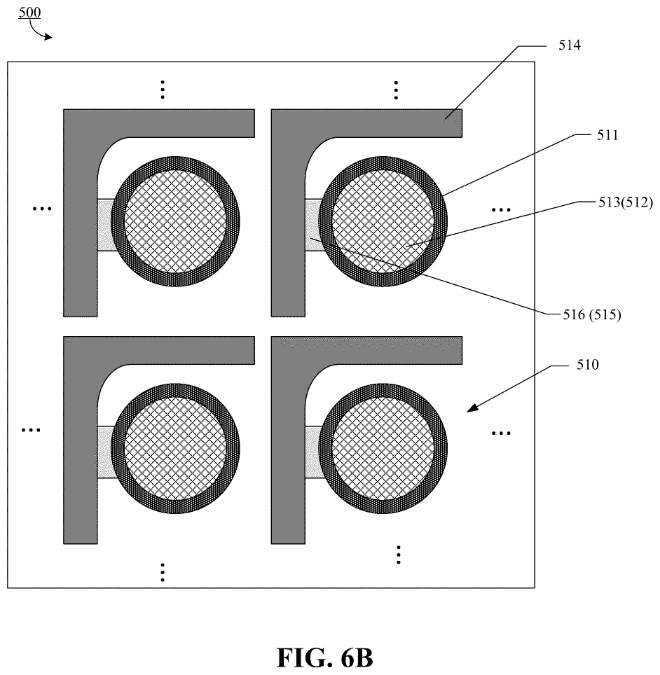

FIG. 6A illustrates a structural diagram showing a top view of micro LED display panel 500 shown in FIG. 5 with top conductive layer and enhance pad removed, according to some embodiments of the present disclosure. Consistent with FIG. 5, referring to FIG. 6A, side connection structure 514 is provided at a side of micro LED 510 (e.g., including bonding layer 511, first light emitting mesa 512, and second light emitting mesa 513). Side connection structure 514 is connected to first light emitting mesa 512 by top connection layer 515 and connected to second light emitting mesa 513 by bottom connection layer 516.

FIG. 6B illustrates a structural diagram showing another top view of micro LED display panel 500 shown in FIG. 5 with top conductive layer and enhance pad removed, according to some embodiments of the present disclosure. Consistent with FIG. 5, referring to FIG. 6B, side connection structure 514 is provided surrounding half of a circumference of micro LED 510 (e.g., including bonding layer 511, first light emitting mesa 512, and second light emitting mesa 513). Side connection structure 514 is connected to first light emitting mesa 512 by top connection layer 515 and connected to second light emitting mesa 513 by bottom connection layer 516. In this example, side connection structure 514 can also isolate light interference from adjacent micro LEDs 510.

With reference to FIG. 1 to FIG. 6B, it can be understood that two or more light emitting mesas can be provided in a vertical direction and electrically connected in series in a similar way.

In some embodiments, the two or more light emitting mesas emit the same color light, thereby increasing the light emission efficiency for a single-color LED.

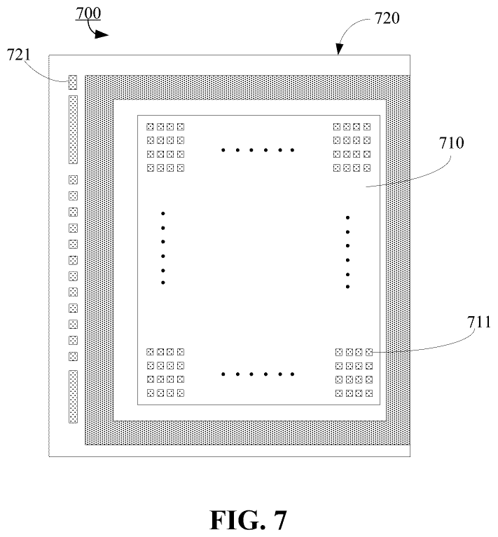

FIG. 7 illustrates a structural diagram showing a top view of a micro LED display panel 700, according to some embodiments of the present disclosure. Referring to FIG. 7, micro LED display panel 700 includes a micro LED array 710 and an IC backplane 720. Micro LED array 710 is located on IC backplane 720 to form an image display area of micro LED display panel 700. The rest of the area on IC backplane 720 not covered by micro LED array 710 is formed as a non-functional area. IC backplane 720 is formed at the back surface of micro LED array 710 with a part extending outside of, i.e., not covered by, micro LED array 710. Micro LED array 710 includes a plurality of micro LEDs 711 provided in an array. IC backplane 720 is configured to control the plurality of micro LEDs 711. IC backplane 720 may include a bottom pad array (not shown) corresponding to micro LED array 710. The bottom pad array includes a plurality of bottom pads (e.g., bottom pads 130, 330, or 530), and one bottom pad corresponds to one micro LED 711. One micro LED of the plurality of micro LEDs is electrically connected with one bottom pad.

In some embodiments, IC backplane 720 further includes a top connected pad 721. A top conductive layer (e.g., top conductive layer 150 in FIG. 1, top conductive layer 340 in FIG. 3, and top conductive layer 540 in FIG. 5) is connected with top connected pad 721.

Each micro LED herein (e.g., micro LED 110, 310, 510) has a very small volume. The micro LED can be applied in a micro LED display panel. The light emitting area of the micro LED display panel, e.g., micro LED display panel 700, is very small, such as 1 mm×1 mm, 3 mm×5 mm, etc. In some embodiments, the light emitting area is the area of the micro LED array in the micro LED display panel. The micro LED display panel includes one or more micro LEDs that form a pixel array in which the micro LEDs are pixels, such as a 1600×1200, 680×480, or 1920×1080-pixel array. The diameter of each micro LED is in the range of about 200 nm to 2 μm. An IC backplane, e.g., IC backplane 720, is formed at the back surface of micro LED array 710 and is electrically connected to micro LED array 710. IC backplane 720 acquires signals such as image data from outside via signal lines to control corresponding micro LEDs 711 to emit light or not.

It is understood by those skilled in the art that the micro LED display panel is not limited by the structure described above, and may include greater or fewer components than those illustrated, or some components may be combined, or a different component may be utilized.

It should be noted that relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED (light emitting diode), comprising:
a bonding layer provided at a bottom of the micro LED; and
two or more light emitting mesas provided on the bonding layer and disposed in a vertical direction from bottom to top, wherein the two or more light emitting mesas are electrically connected in series.

2. The micro LED according to claim 1, wherein the two or more light emitting mesas comprise:
a first light emitting mesa provided on the bonding layer and electrically connected to the bonding layer; and
a second light emitting mesa provided above the first light emitting mesa, a top of the first light emitting mesa electrically connected to a bottom of the second light emitting mesa.

3. The micro LED according to claim 2, further comprising a connection structure provided between the first light emitting mesa and the second light emitting mesa to connect the first light emitting mesa and the second light emitting mesa in series.

4. The micro LED according to claim 3, wherein the connection structure is a metal via.

5. The micro LED according to claim 3, wherein the connection structure is a second bonding layer.

6. The micro LED according to claim 5, wherein a light emitting area of the first light emitting mesa is greater than a light emitting area of the second light emitting mesa.

7. The micro LED according to claim 2, further comprising a side connection structure provided at a side of the two or more light emitting mesas and connects the first light emitting mesa and the second light emitting mesa in series, wherein the first light emitting mesa comprises a top connection layer formed at a top of the first light emitting mesa and electrically connected to the side connection structure; and the second light emitting mesa comprises a bottom connection layer formed at a bottom of the second light emitting mesa and electrically connected to the side connection structure.

8. The micro LED according to claim 7, wherein the side connection structure is further configured to provide light isolation.

9. The micro LED according to claim 1, wherein the two or more light emitting mesas emit the same color light.

10. A micro LED (light emitting diode) display panel comprises:
an integrated circuit (IC) backplane comprising a bottom pad array, the bottom pad array comprising a plurality of bottom pads; and
a micro LED array formed on the IC backplane, the micro LED array comprising a plurality of micro LEDs;
wherein one micro LED of the plurality of micro LEDs is electrically connected to one bottom pad of the plurality of bottom pads, and each of the plurality of micro LEDs comprises:
a bonding layer bonded with the IC backplane; and
two or more light emitting mesas formed on the bonding layer, wherein the two or more light emitting mesas are disposed in a vertical direction from bottom to top and electrically connected in series.

11. The micro LED display panel according to claim 10, wherein the two or more light emitting mesas comprise:
a first light emitting mesa provided on the bonding layer and electrically connected to the bonding layer; and
a second light emitting mesa provided above the first light emitting mesa, a top of the first light emitting mesa electrically connected to a bottom of the second light emitting mesa.

12. The micro LED display panel according to claim 11, further comprising a top conductive layer continuously formed on a top surface of the micro LED array and electrically connected to the top of second light emitting mesa.

13. The micro LED display panel according to claim 12, further comprising a connection structure provided between the first light emitting mesa and the second light emitting mesa to connect the first light emitting mesa and the second light emitting mesa in series.

14. The micro LED display panel according to claim 13, further comprises an isolation structure provided between adjacent micro LEDs to isolate light interference between the adjacent micro LEDs.

15. The micro LED display panel according to claim 14, wherein the isolation structure is provided on the top conductive layer, a bottom of the isolation structure being lower than or equal to a bottom of the first light emitting mesa, and a top of the isolation structure being higher than or equal to a bottom of the second light emitting mesa.

16. The micro LED display panel according to claim 14, wherein the isolation structure has a structure with a truncated cone shape.

17. The micro LED display panel according to claim 16, wherein the isolation structure comprises an isolation core and a reflective layer formed on a surface of the isolation core.

18. The micro LED display panel according to claim 17, wherein a material of the isolation core is photosensitive polyimide (PSPI).

19. The micro LED display panel according to claim 14, further comprising an enhance pad provided on the top conductive layer, wherein the enhance pad being at a bottom of the isolation structure.

20. The micro LED display panel according to claim 12, further comprising an enhance pad provided on the top conductive layer and between adjacent ones of the plurality of micro LEDs, the enhance pad configured to increase conductivity of the top conductive layer.

21. The micro LED display panel according to claim 12, wherein the IC backplane further comprises a top connected pad, and the top conductive layer is connected to the top connected pad of the IC backplane.
